(19) United States
(12) Patent Application Publication
(10) Pub. No.: US 2024/0413203 A1
(43) Pub. Date: Dec. 12, 2024

(54) SEMICONDUCTOR DEVICE

(71) Applicant: SAMSUNG ELECTRONICS CO., LTD., SUWON-SI (KR)

(72) Inventors: Chang Min YOE, Suwon-si (KR); Ji Wang KO, Suwon-si (KR); Jae Hong CHOI, Suwon-si (KR); Jun Ho HONG, Suwon-si (KR); Dong Min KIM, Suwon-si, Gyeonggi-do (KR); Jeong Min CHOI, Suwon-si (KR)

(21) Appl. No.: 18/543,414

(22) Filed: Dec. 18, 2023

(30) Foreign Application Priority Data
Jun. 12, 2023 (KR) 10-2023-0074685

(51) Int. Cl. H01L 29/06; H01L 29/417; H01L 29/423; H01L 29/775; H01L 29/786

(52) U.S. Cl. CPC H01L 29/0673; H01L 29/41775; H01L 29/42392; H01L 29/775; H01L 29/78696

(57) ABSTRACT

A semiconductor device includes a substrate. An active pattern is on the substrate and extends in a first horizontal direction. First to third nanosheets are sequentially stacked on the active pattern and are spaced apart from each other in a vertical direction. A gate electrode is on the active pattern and extends in a second horizontal direction. The gate electrode surrounds each of the first to third nanosheets. A source/drain region is on the active pattern on at least one side of the gate electrode. An interlayer insulating layer covers the source/drain region. A source/drain contact penetrates the interlayer insulating layer in the vertical direction and is connected to the source/drain region. At least a portion of the interlayer insulating layer is disposed between sidewalls of the source/drain contact and the source/drain region in the first horizontal direction and overlaps sidewalls of the third nanosheet along the first horizontal direction.

### CROSS-REFERENCE TO RELATED APPLICATION

This application claims priority under 35 U.S.C. § 119 to Korean Patent Application No. 10-2023-0074685, filed on Jun. 12, 2023 in the Korean Intellectual Property Office, the disclosure of which is incorporated by reference in its entirety herein.

### 1. TECHNICAL FIELD

The present disclosure relates to a semiconductor device, and more particularly, to a semiconductor device including a Multi-Bridge Channel Field Effect Transistor (MBCFET™).

### 2. DISCUSSION OF RELATED ART

A multi-gate transistor is being developed for a scaling technique to increase the density of a semiconductor device. In a multi-gate transistor, a fin-type or nanowire-type silicon body is formed on a substrate and a gate is formed on the surface of the multi-channel active pattern.

As the multi-gate transistor uses a three-dimensional (3D) channel, scaling can be facilitated to increase the density of the semiconductor device. Furthermore, current control capabilities may be increased without requiring an increase in the gate length of the multi-gate transistor. Additionally, a short channel effect (SCE) in which there is a potential disruption of the channel region caused by a drain voltage may be prevented.

### SUMMARY

Aspects of embodiments of the present disclosure provide a semiconductor device which can prevent the occurrence of a short circuit between a source/drain contact and a gate electrode by partially etching upper parts of source/drain regions that are connected to the source/drain contact.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an embodiment of the present disclosure, a semiconductor device includes a substrate. An active pattern is on the substrate. The active pattern extends in a first horizontal direction. First, second, and third nanosheets are sequentially stacked on the active pattern. The first to third nanosheets are spaced apart from each other in a vertical direction. The third nanosheet is an uppermost nanosheet of the first to third nanosheets. A gate electrode is on the active pattern and extends in a second horizontal direction crossing the first horizontal direction. The gate electrode surrounds each of the first, second, and third nanosheets. A source/drain region is on the active pattern and is disposed on at least one side of the gate electrode. An interlayer insulating layer covers the source/drain region. A source/drain contact penetrates the interlayer insulating layer in the vertical direction. The source/drain contact is connected to the source/drain region. At least a portion of the interlayer insulating layer is disposed between sidewalls of the source/drain contact and the source/drain region in the first horizontal direction. The at least portion of the interlayer insulating layer overlaps sidewalls of the third nanosheet along the first horizontal direction.

According to an embodiment of the present disclosure, a semiconductor device includes a substrate. An active pattern is on the substrate. The active pattern extends in a first horizontal direction. First, second, and third nanosheets are sequentially stacked on the active pattern. The first to third nanosheets are spaced apart from each other in a vertical direction. The third nanosheet is an uppermost nanosheet of the first to third nanosheets. A gate electrode is on the active pattern. The gate electrode extends in a second horizontal direction crossing the first horizontal direction. The gate electrode surrounds each of the first, second, and third nanosheets. A source/drain region is on the active pattern and is disposed on at least one side of the gate electrode. An etching stop layer is disposed along a top surface of the source/drain region. A source/drain contact penetrates the etching stop layer in the vertical direction. The source/drain contact is connected to the source/drain region. A silicide layer is disposed between a bottom surface of the source/drain contact and the source/drain region. The silicide layer is not disposed on sidewalls of the source/drain contact. At least a portion of the etching stop layer is disposed between sidewalls of the source/drain contact and the source/drain region. The at least portion of the etching stop layer overlaps sidewalls of the third nanosheet along the first horizontal direction.

According to an embodiment of the present disclosure, a semiconductor device includes a substrate. An active pattern is on the substrate. The active pattern extends in a first horizontal direction on the substrate. First, second, and third nanosheets are sequentially stacked on the active pattern. The first to third nanosheets are spaced apart from each other in a vertical direction. The third nanosheet is an uppermost nanosheet of the first to third nanosheets. A gate electrode is on the active pattern and extends in a second horizontal direction crossing the first horizontal direction. The gate electrode surrounds each of the first, second, and third nanosheets. A source/drain region is on the active pattern and is disposed on at least one side of the gate electrode. An etching stop layer is disposed along a top surface of the source/drain region. An interlayer insulating layer is disposed on the etching stop layer. A source/drain contact penetrates the etching stop layer and the interlayer insulating layer in the vertical direction. The source/drain contact is connected to the source/drain region. A silicide layer is disposed between a bottom surface of the source/drain contact and the source/drain region. The silicide layer is not disposed on sidewalls of the source/drain contact. At least a portion of the etching stop layer and at least a portion of the interlayer insulating layer is disposed between the sidewalls of the source/drain contact and the source/drain region. The at least portion of the etching stop layer and the at least portion of the interlayer insulating layer overlap the third nanosheet along the first horizontal direction. Inner sidewalls of the source/drain region that face the sidewalls of the source/drain contact have a rectilinearly inclined profile extending from the bottom surface of the source/drain contact towards the sidewalls of the third nanosheet.

It should be noted that the effects of embodiments of the present disclosure are not limited to those described above, and other effects of embodiments of the present disclosure will be apparent from the following description.

### BRIEF DESCRIPTION OF THE DRAWINGS

The above and other aspects and features of embodiments of the present disclosure will become more apparent by describing in detail embodiments thereof with reference to the attached drawings, in which.

FIG. 1 is a layout view of a semiconductor device according to an embodiment of the present disclosure;

FIG. 2 is a cross-sectional view taken along line A-A′ of FIG. 1 according to an embodiment of the present disclosure;

FIG. 3 is an enlarged cross-sectional view of a region R1 of FIG. 2 according to an embodiment of the present disclosure;

FIG. 4 is a cross-sectional view taken along line B-B′ of FIG. 1 according to an embodiment of the present disclosure;

FIGS. 5 through 19 are cross-sectional views illustrating intermediate steps of a method of fabricating a semiconductor device according to some embodiments of the present disclosure;

FIG. 20 is a cross-sectional view of a semiconductor device according to an embodiment of the present disclosure;

FIG. 21 is a cross-sectional view of a semiconductor device according to an embodiment of the present disclosure;

FIG. 22 is an enlarged cross-sectional view of a region R2 of FIG. 21 according to an embodiment of the present disclosure;

FIG. 23 is a cross-sectional view of a semiconductor device according to an embodiment of the present disclosure;

FIG. 24 is an enlarged cross-sectional view of a region R3 of FIG. 23 according to an embodiment of the present disclosure;

FIG. 25 is a cross-sectional view of a semiconductor device according to an embodiment of the present disclosure;

FIG. 26 is an enlarged cross-sectional view of a region R4 of FIG. 25 according to an embodiment of the present disclosure;

FIG. 27 is a cross-sectional view of a semiconductor device according to an embodiment of the present disclosure;

FIG. 28 is a cross-sectional view of a semiconductor device according to an embodiment of the present disclosure; and

FIG. 29 is a cross-sectional view of a semiconductor device according to an embodiment of the present disclosure.

### DETAILED DESCRIPTION OF EMBODIMENTS

A semiconductor device according to some embodiments of the present disclosure will hereinafter be described as including a Multi-Bridge Channel Field Effect Transistor (MBCFET™) including nanosheets. However, embodiments of the present disclosure are not necessarily limited thereto. A semiconductor device according to some embodiments of the present disclosure may include a fin field-effect transistor (FinFET) including fin-type channel regions, a tunneling field-effect transistor (FET), or a three-dimensional (3D) transistor. A semiconductor device according to some embodiments of the present disclosure may include a bipolar junction transistor or a lateral double-diffused metal-oxide-semiconductor field-effect transistor (LDMOS).

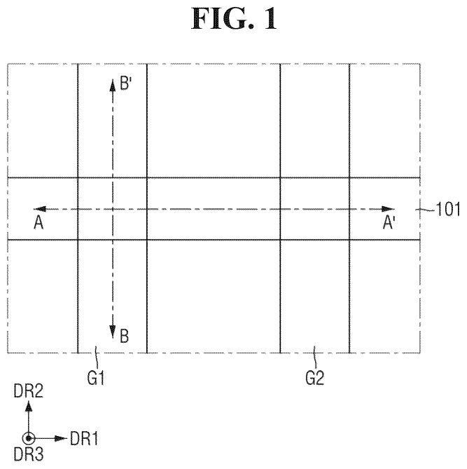

A semiconductor device according to some embodiments of the present disclosure will hereinafter be described with reference to FIGS. 1 through 4.

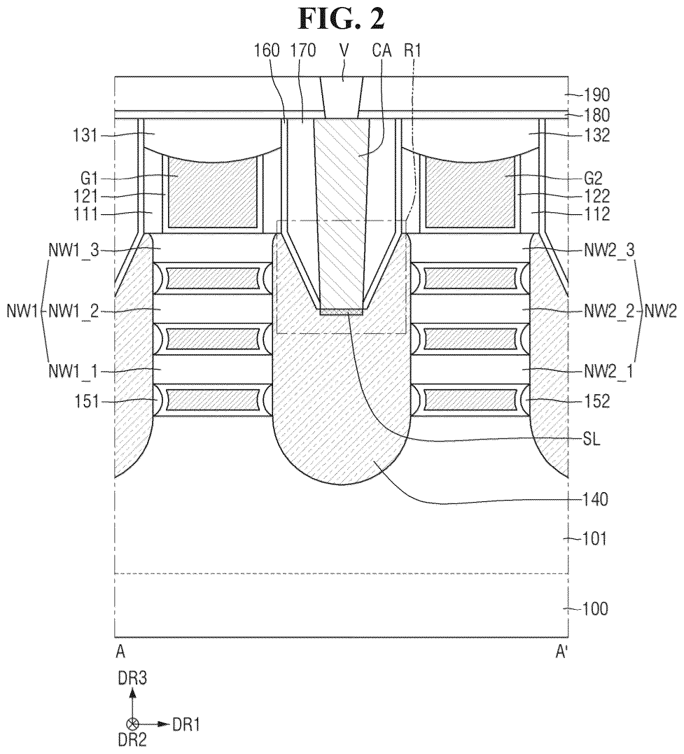

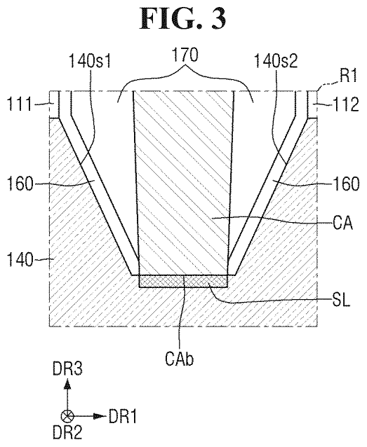

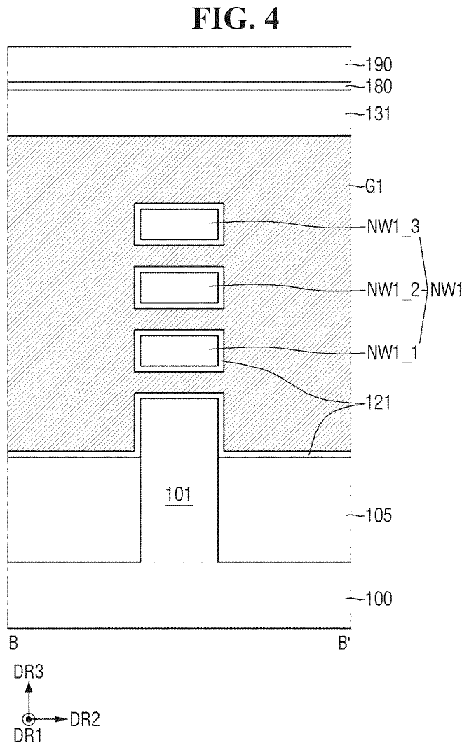

FIG. 1 is a layout view of a semiconductor device according to some embodiments of the present disclosure. FIG. 2 is a cross-sectional view taken along line A-A′ of FIG. 1. FIG. 3 is an enlarged cross-sectional view of a region R1 of FIG. 2. FIG. 4 is a cross-sectional view taken along line B-B′ of FIG. 1.

Referring to FIGS. 1 through 4, the semiconductor device according to some embodiments of the present disclosure includes a substrate 100, an active pattern 101, a first plurality of nanosheets NW1, a second plurality of nanosheets NW2, first and second gate electrodes G1 and G2, first gate spacers 111, second gate spacers 112, first and second gate insulating layers 121 and 122, first and second capping patterns 131 and 132, a source/drain region 140, first inner spacers 151, second inner spacers 152, a first etching stop layer 160, a first interlayer insulating layer 170, a source/drain contact CA, a silicide layer SL, a second etching stop layer 180, a second interlayer insulating layer 190, and a via V.

In an embodiment, the substrate 100 may be a silicon (Si) substrate or a silicon-on-insulator (SOI) substrate. Alternatively, the substrate 100 may include silicon-germanium (SiGe), silicon-germanium-on insulator (SGOI), indium antimonide, a lead tellurium compound, indium arsenide, indium phosphide, gallium arsenide, or gallium antimonide. However, embodiments of the present disclosure are not necessarily limited thereto.

First and second horizontal directions DR1 and DR2 may be defined as directions parallel to the top surface of the substrate 100. The second horizontal direction DR2 may cross the first horizontal direction DR1. In an embodiment, the second direction DR2 may cross the first direction DR1. However, embodiments of the present disclosure are not necessarily limited thereto. A vertical direction DR3 may be defined as a direction perpendicular to the first and second horizontal directions DR1 and DR2. For example, the vertical direction DR3 may be perpendicular to the top surface of the substrate 100.

The active pattern 101 may extend in the first horizontal direction DR1 on the substrate 100. The active pattern 101 may protrude in the vertical direction DR3 from the top surface of the substrate 100. For example, in an embodiment the active pattern 101 may be a portion of the substrate 100 and may include an epitaxial layer grown from the substrate 100.

The field insulating layer 105 may be disposed on the top surface of the substrate 100 (e.g., disposed directly thereon in the third direction DR3). The field insulating layer 105 may surround the sidewalls of the active pattern 101. For example, the top surface of the active pattern 101 may protrude in the vertical direction DR3 beyond the top surface of the field insulating layer 105. However, embodiments of the present disclosure are not necessarily limited thereto. Alternatively, in some embodiments, the top surface of the active pattern 101 may be disposed on the same plane as the top surface of the field insulating layer 105 (e.g., in the third direction DR3). In an embodiment, the field insulating layer 105 may include, for example, an oxide film, a nitride film, an oxynitride film, or a combination thereof.

The first nanosheets NW1 and the second nanosheets NW2 may be disposed on the active pattern 101. The second nanosheets NW2 may be spaced apart in the first horizontal direction DR1 from the first nanosheets NW1. The first nanosheets NW1 may include a plurality of nanosheets that are stacked on the active pattern 101 to be spaced apart in the vertical direction DR3 from one another, and the second nanosheets NW2 may also include a plurality of nanosheets that are stacked on the active pattern 101 to be spaced apart in the vertical direction DR3 from one another.

For example, in an embodiment the first nanosheets NW1 may include first, second, and third nanosheets NW1_1, NW1_2, and NW1_3, which are sequentially stacked in the vertical direction DR3 on the active pattern 101 to be spaced apart from one another. For example, the first nanosheet NW1_1 may be disposed on the active pattern 101, the second nanosheet NW1_2 may be disposed on the first nanosheet NW1_1, and the third nanosheet NW1_3 may be disposed on the second nanosheet NW1_2. For example, the third nanosheet NW1_3 may be the uppermost nanosheet among the first nanosheets NW1.

For example, in an embodiment the second nanosheets NW2 may include fourth, fifth, and sixth nanosheets NW2_1, NW2_2, and NW2_3, which are sequentially stacked in the vertical direction DR3 on the active pattern 101 to be spaced apart from one another. For example, the fourth nanosheet NW2_1 may be disposed on the active pattern 101, the fifth nanosheet NW2_2 may be disposed on the fourth nanosheet NW2_1, and the sixth nanosheet NW2_3 may be disposed on the fifth nanosheet NW2_2. For example, the sixth nanosheet NW2_3 may be the uppermost nanosheet among the second nanosheets NW2.

For example, the fourth, fifth, and sixth nanosheets NW2_1, NW2_2, and NW2_3 may be spaced apart from the first, second, and third nanosheets NW1_1, NW1_2, and NW1_3, respectively, in the first horizontal direction DR1. The fourth, fifth, and sixth nanosheets NW2_1, NW2_2, and NW2_3 may be disposed on the same vertical level as the first, second, and third nanosheets NW1_1, NW1_2, and NW1_3, respectively. FIGS. 2 and 4 illustrate that three first nanosheets NW1 are stacked in the vertical direction DR3 to be spaced apart from one another and three second nanosheets NW2 are stacked in the vertical direction DR3 to be spaced apart from one another. However, embodiments of the present disclosure are not necessarily limited thereto and the number of the nanosheets included in each of the first and second nanosheets NW1, NW2 may vary in some embodiments. For example, in some embodiments, four first nanosheets NW1 may be stacked in the vertical direction DR3 to be spaced apart from one another, and four second nanosheets NW2 may be stacked in the vertical direction DR3 to be spaced apart from one another. For example, the first nanosheets NW1 and the second nanosheets NW2 may include Si. However, embodiments of the present disclosure are not necessarily limited thereto. Alternatively, in some embodiments, the first nanosheets NW1 and the second nanosheets NW2 may include SiGe.

The first gate electrode G1 may extend in the second horizontal direction DR2 on the active pattern 101 and the field insulating layer 105. The first gate electrode G1 may surround the first nanosheets NW1. The second gate electrode G2 may extend in the second horizontal direction DR2 on the active pattern 101 and the field insulating layer 105. The second gate electrode G2 may be spaced apart from the first gate electrode G1 in the first horizontal direction DR1. The second gate electrode G2 may surround the second nanosheets NW2.

In an embodiment, the first and second gate electrodes G1 and G2 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. However, embodiments of the present disclosure are not necessarily limited thereto. In an embodiment, the first and second gate electrodes G1 and G2 may include a conductive metal oxide or a conductive metal oxynitride and may include oxidized forms of the aforementioned materials.

The first gate spacers 111 may be disposed on (e.g., disposed directly thereon in the third direction DR3) the top surface of the third nanosheet NW1_3 and the field insulating layer 105. For example, the first gate spacers 111 may be in direct contact with the top surface of the third nanosheet NW1_3. The first gate spacers 111 may extend in the second horizontal direction DR2 on both sidewalls (e.g., sidewalls that are spaced apart from each other in the first horizontal direction DR1) of the first gate electrode G1. The second gate spacers 112 may be disposed on (e.g., disposed directly thereon in the third direction DR3) the top surface of the sixth nanosheet NW2_3 and the field insulating layer 105. For example, the second gate spacers 112 may be in direct contact with the top surface of the sixth nanosheet NW2_3. The second gate spacers 112 may extend in the second horizontal direction DR2 on both sidewalls (e.g., sidewalls that are spaced apart from each other in the first horizontal direction DR1) of the second gate electrode G2.

In an embodiment, the first gate spacers 111 and the second gate spacers 112 may include at least one of, for example, silicon nitride (SiN), silicon oxynitride (SiON), silicon oxide (SiO2), silicon oxycarbonitride (SiOCN), silicon boron nitride (SiBN), silicon oxyboronitride (SiOBN), silicon oxycarbide (SiOC), and a combination thereof. However, embodiments of the present disclosure are not necessarily limited thereto.

The first gate insulating layer 121 may be disposed between (e.g., disposed directly therebetween) the first gate electrode G1 and the first gate spacers 111. The first gate insulating layer 121 may be disposed between the first gate electrode G1 and the source/drain region 140. The first gate insulating layer 121 may be disposed between the first gate electrode G1 and the active pattern 101. The first gate insulating layer 121 may be disposed between the first gate electrode G1 and the field insulating layer 105. The first gate insulating layer 121 may be disposed between the first gate electrode G1 and the first nanosheets NW1.

The second gate insulating layer 122 may be disposed between the second gate electrode G2 and the second gate spacers 112. The second gate insulating layer 122 may be disposed between the second gate electrode G2 and the source/drain region 140. The second gate insulating layer 122 may be disposed between the second gate electrode G2 and the active pattern 101. The second gate insulating layer 122 may be disposed between the second gate electrode G2 and the field insulating layer 105. The second gate insulating layer 122 may be disposed between the second gate electrode G2 and the second nanosheets NW2.

In an embodiment, the first and second gate insulating layers 121 and 122 may include silicon oxide, silicon oxynitride, silicon nitride, or a high-k material having a greater dielectric constant than silicon oxide. The high-k material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The semiconductor device according to some embodiments of the present disclosure may include a negative capacitance (NC) FET using a negative capacitor. For example, in an embodiment each of the first and second gate insulating layers 121 and 122 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film can have a sub-threshold swing (SS) of less than about 60 m V/decade at room temperature.

The ferroelectric material film may have ferroelectric properties. In an embodiment, the ferroelectric material film may include at least one of, for example, hafnium oxide, hafnium zirconium oxide, barium strontium titanium oxide, barium titanium oxide, and lead zirconium titanium oxide. For example, the hafnium zirconium oxide may be a material obtained by doping hafnium oxide with zirconium (Zr). However, embodiments of the present disclosure are not necessarily limited thereto. For example, in an embodiment the hafnium zirconium oxide may be a compound of hafnium (Hf), Zr, and oxygen (O).

The ferroelectric material film may further include a dopant. For example, in an embodiment the dopant may include at least one of Al, Ti, Nb, lanthanum (La), yttrium (Y), magnesium (Mg), silicon, calcium (Ca), cerium (Ce), dysprosium (Dy), erbium (Er), gadolinium (Gd), germanium, scandium (Sc), strontium (Sr), and tin (Sn). The type of dopant may vary depending on the type of material of the ferroelectric material film.

For example, in an embodiment in which the ferroelectric material film includes hafnium oxide, the dopant of the ferroelectric material film may include at least one of, for example, Gd, Si, Zr, Al, and Y.

In an embodiment in which the dopant of the ferroelectric material film is Al, the ferroelectric material film may include about 3 atomic % (at %) to about 8 at % of Al. Here, the ratio of the dopant in the ferroelectric material film may refer to the ratio of the sum of the amounts of Hf and Al to the amount of Al in the ferroelectric material film.

In an embodiment in which the dopant of the ferroelectric material film is Si, the ferroelectric material film may include about 2 at % to about 10 at % of Si. In an embodiment in which the dopant of the ferroelectric material film is Y, the ferroelectric material film may include about 2 at % to about 10 at % of Y. In an embodiment in which the dopant of the ferroelectric material film is Gd, the ferroelectric material film may include about 1 at % to about 7 at % of Gd. In an embodiment in which the dopant of the ferroelectric material film is Zr, the ferroelectric material film may include about 50 at % to about 80 at % of Zr.

The paraelectric material film may include paraelectric properties. In an embodiment, the paraelectric material film may include at least one of, for example, silicon oxide and a high-k metal oxide. The high-k metal oxide may include at least one of, for example, hafnium oxide, zirconium oxide, and aluminum oxide. However, embodiments of the present disclosure are not necessarily limited thereto.

The ferroelectric material film and the paraelectric material film may include the same material. The ferroelectric material film may have ferroelectric properties, but the paraelectric material film may not have ferroelectric properties. For example, in an embodiment in which the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. In an embodiment, the ferroelectric material film may have a thickness of, for example, about 0.5 nm to about 10 nm. However, embodiments of the present disclosure are not necessarily limited thereto. A critical thickness that can exhibit ferroelectric properties may vary depending on the type of ferroelectric material, and thus, the thickness of the ferroelectric material film may vary depending on the type of ferroelectric material included in the ferroelectric material film.

For example, each of the first and second gate insulating layers 121 and 122 may include one ferroelectric material film. However, embodiments of the present disclosure are not necessarily limited thereto. For example, in an embodiment each of the first and second gate insulating layers 121 and 122 may include a plurality of ferroelectric material films that are spaced apart from one another. Each of the first and second gate insulating layers 121 and 122 may have a structure in which a plurality of ferroelectric material films and a plurality of paraelectric material films are alternately stacked.

The first capping pattern 131 may extend in the second horizontal direction DR2 on the top surface of the first gate electrode G1, the uppermost surface of the first gate insulating layer 121, and the uppermost surfaces of the first gate spacers 111. The second capping pattern 132 may extend in the second horizontal direction DR2 on the top surface of the second gate electrode G2, the uppermost surface of the second gate insulating layer 122, and the uppermost surfaces of the second gate spacers 112.

For example, in an embodiment the first capping pattern 131 may be in direct contact with the uppermost surfaces of the first gate spacers 111, and the second capping pattern 132 may be in direct contact with the uppermost surfaces of the second gate spacers 112. However, embodiments of the present disclosure are not necessarily limited thereto. Alternatively, in some embodiments, the first capping pattern 131 may be disposed between the first gate spacers 111, and the second capping pattern 132 may be disposed between the second gate spacers 112. In an embodiment, the first and second capping patterns 131 and 132 may include at least one of, for example, SiN, SiON, SiO2, silicon carbonitride (SiCN), SiOCN, and a combination thereof. However, embodiments of the present disclosure are not necessarily limited thereto.

The source/drain region 140 may be disposed on at least one side of each of the first and second gate electrodes G1 and G2. For example, the source/drain region 140 may be disposed between the first and second gate electrodes G1 and G2 (e.g., in the first direction DR1), on the active pattern 101. For example, the source/drain region 140 may be in direct contact with both sidewalls (e.g., sidewalls spaced apart from each other in the first horizontal direction DR1) of each of the first nanosheets NW1 and the second nanosheets NW2.

In an embodiment, an upper trench may be formed above the source/drain region 140. The upper trench may be positioned between the set of the first nanosheets NW1 and the set of the second nanosheets NW2 (e.g., in the first direction DR1). The upper trench may be formed to be recessed from the top surfaces of the third and sixth nanosheets NW1_3 and NW2_3 towards the substrate 100. For example, as shown in FIG. 3 a sidewall of the upper trench that is formed near the first nanosheets NW1 may be defined as a first inner sidewall 140s1 of the source/drain region 140, and a sidewall of the upper trench that is formed near the second nanosheets NW2 may be defined as a second inner sidewall 140s2 of the source/drain region 140. For example, the bottom surface of the upper trench may be formed on the sidewalls (e.g., sidewalls spaced apart from each other in the first horizontal direction DR1) of the second and fifth nanosheets NW1_2 and NW2_2.

For example, the width in the first horizontal direction DR1 of the upper trench may gradually increase closer to the top surfaces of the third and sixth nanosheets NW1_3 and NW2_3. For example, as shown in an embodiment of FIG. 3 the first inner sidewall 140s1 of the source/drain region 140 may have a rectilinearly inclined profile, extending from the bottom surface of the upper trench towards the sidewall of the third nanosheet NW1_3. For example, in a cross-sectional view taken along the first horizontal direction DR1, the first inner sidewall 140s1 of the source/drain region 140 may have a rectilinearly inclined profile. For example, the second inner sidewall 140s2 of the source/drain region 140 may have a rectilinearly inclined profile, extending from the bottom surface of the upper trench towards the sidewall of the sixth nanosheet NW2_3. For example, in the cross-sectional view taken along the first horizontal direction DR1, the second inner sidewall 140s2 of the source/drain region 140 may have a rectilinearly inclined profile.

The first inner spacers 151 may be disposed on (e.g., disposed directly thereon) both sidewalls of the first gate electrode G1 (e.g., sidewalls spaced apart from each other in the first horizontal direction DR1) between the first nanosheets NW1. The first inner spacers 151 may also be disposed on (e.g., disposed directly thereon) both sidewalls of the first gate electrode G1 (e.g., sidewalls spaced apart from each other in the first horizontal direction DR1) between the active pattern 101 and the first nanosheet NW1_1. The first inner spacers 151 may be disposed between (e.g., disposed directly therebetween) the first gate insulating layer 121 and the source/drain region 140.

The second inner spacers 152 may be disposed on (e.g., disposed directly thereon) both sidewalls of the second gate electrode G2 (e.g., sidewalls spaced apart from each other in the first horizontal direction DR1) between the second nanosheets NW2. The second inner spacers 152 may also be disposed on (disposed directly thereon) both sidewalls of the second gate electrode G2 (e.g., sidewalls spaced apart from each other in the first horizontal direction DR1) between the active pattern 101 and the fourth nanosheet NW2_1. The second inner spacers 152 may be disposed between (e.g., disposed directly therebetween) the second gate insulating layer 122 and the source/drain region 140.

In an embodiment, the first inner spacers 151 and the second inner spacers 152 may include at least one of, for example, SiN, SiON, SiO2, SiOCN, SiBN, SiOBN, SiOC, and a combination thereof. However, embodiments of the present disclosure are not necessarily limited thereto.

The first etching stop layer 160 may be disposed along (e.g., disposed directly along) the top surfaces of the source/drain region 140. The first etching stop layer 160 may be disposed on (e.g., disposed directly thereon) the sidewalls of each of the first gate spacers 111, the second gate spacers 112, the first capping pattern 131, and the second capping pattern 132. In an embodiment, the first etching stop layer 160 may be disposed even on the sidewalls, in the second horizontal direction DR2, of the source/drain region 140 and on the field insulating layer 105. For example, the first etching stop layer 160 may be conformally formed. For example, the uppermost surface of the first etching stop layer 160 may be formed on the same plane (e.g., in the third direction DR3) as the top surfaces of the first and second capping patterns 131 and 132. However, embodiments of the present disclosure are not necessarily limited thereto. In an embodiment, the first etching stop layer 160 may include at least one of, for example, aluminum oxide, aluminum nitride, hafnium oxide, zirconium oxide, silicon oxide, silicon nitride, silicon oxynitride, and a low-k material.

The first interlayer insulating layer 170 may be disposed on (e.g., disposed directly thereon) the first etching stop layer 160. For example, the first interlayer insulating layer 170 may cover the source/drain regions, on the first etching stop layer 160. For example, the first etching stop layer 160 may be disposed between (e.g., disposed directly therebetween) the first interlayer insulating layer 170 and the source/drain region 140. For example, in an embodiment the top surface of the first interlayer insulating layer 170 may be disposed on the same plane (e.g., in the third direction DR3) as the top surfaces of the first and second capping patterns 131 and 132. However, embodiments of the present disclosure are not necessarily limited thereto. Alternatively, in some embodiments, the first interlayer insulating layer 170 may cover the top surfaces of the first and second capping patterns 131 and 132.

In an embodiment, the first interlayer insulating layer 170 may include at least one of, for example, silicon oxide, silicon nitride, silicon oxynitride, and a low-k material. The low-k material may include, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), TOSZ, fluoride silicate glass (FSG), polyimide nanofoam (such as polypropylene oxide), carbon doped silicon oxide (CDO), organo silicate glass (OSG), SiLK, amorphous fluorinated carbon, silica aerogel, silica xerogel, mesoporous silica, and a combination thereof. However, embodiments of the present disclosure are not necessarily limited thereto.

The source/drain contact CA may penetrate the first interlayer insulating layer 170 and the first etching stop layer 160 in the vertical direction DR3 and may thereby be connected to the source/drain region 140. For example, a bottom surface CAb of the source/drain contact CA may be disposed on the same plane (e.g., in the third direction DR3) as the bottom surface of the upper trench, which is defined by the first and second inner sidewalls 140s1 and 140s2 of the source/drain region 140. For example, a first sidewall, in the first horizontal direction DR1, of the source/drain contact CA may be defined as the sidewall of the source/drain contact CA that faces the first inner sidewall 140s1 of the source/drain region 140, and a second sidewall, in the first horizontal direction DR1, of the source/drain contact CA may be defined as the sidewall of the source/drain contact CA that faces second inner sidewall 140s2 of the source/drain region 140.

For example, at least a portion of the first interlayer insulating layer 170 may be disposed between a first sidewall, in the first horizontal direction DR1, of the source/drain contact CA and the first inner sidewall 140s1 of the source/drain region 140, above the third nanosheet NW1_3 in the first horizontal direction DR1. For example, at least a portion of the first interlayer insulating layer 170 may also be disposed between the second sidewall, in the first horizontal direction DR1, of the source/drain contact CA and the second inner sidewall 140s2 of the source/drain region 140, above the sixth nanosheet NW2_3 in the first horizontal direction DR1.

For example, at least a portion of the etching stop layer 160 may be disposed between the first sidewall, in the first horizontal direction DR1, of the source/drain contact CA and the first inner sidewall 140s1 of the source/drain region 140, above the third nanosheet NW1_3 in the first horizontal direction DR1. For example, at least a portion of the etching stop layer 160 may also be disposed between the second sidewall, in the first horizontal direction DR1, of the source/drain contact CA and the second inner sidewall 140s2 of the source/drain region 140, above the sixth nanosheet NW2_3 in the first horizontal direction DR1.

For example, the first interlayer insulating layer 170 may be disposed between the first etching stop layer 160 and the source/drain contact CA, on the sidewalls of the first gate spacers 111. For example, the first interlayer insulating layer 170 may also be disposed between the first etching stop layer 160 and the source/drain contact CA, on the sidewalls of the second gate spacers 112. For example, the first and second sidewalls, in the first horizontal direction DR1, of the source/drain contact CA may be in direct contact with at least a portion of the first etching stop layer 160, on the bottom surface of the upper trench.

For example, the first and second sidewalls, in the first horizontal direction DR1, of the source/drain contact CA are not in direct contact with the source/drain region 140. For example, the first and second inner sidewalls 140s1 and 140s2 of the source/drain region 140 may be spaced apart in the first horizontal direction DR1 from the source/drain contact CA by the first etching stop layer 160 and the first interlayer insulating layer 170. For example, the bottom surface CAb of the source/drain contact CA may be flat. For example, the bottom surface CAb of the source/drain contact CA may be formed to extend substantially parallel to the top surface of the substrate 100. For example, in an embodiment, the bottom surface CAb of the source/drain contact CA may be formed at a same height from the top surface of the substrate 100 (e.g., in the third direction DR3) as the sidewalls, in the first horizontal direction DR1, of the second and fifth nanosheets NW1_2 and NW2_2.

For example, in an embodiment the top surface of the source/drain contact CA may be positioned on the same plane (e.g., in the third direction DR3) as the top surface of the first interlayer insulating layer 170. For example, the source/drain contact CA may be formed as a single film. In an embodiment, the source/drain contact CA may include one of, for example, Ta, TaN, Ti, TiN, Ru, Co, Ni, nickel boron (NiB), W, WN, tungsten carbonitride (WCN), Zr, zirconium nitride (ZrN), V, vanadium nitride (VN), Nb, NbN, Pt, Ir, Rh, Al, Cu, and Mo.

The silicide layer SL may be disposed between (e.g., directly between) the bottom surface CAb of the source/drain contact CA and the source/drain region 140. For example, the silicide layer SL may not be disposed on both sidewalls of the source/drain contact CA in the first horizontal direction DR1. FIG. 3 illustrates that the silicide layer SL is not in direct contact with the first etching stop layer 160. However, embodiments of the present disclosure are not necessarily limited thereto. Alternatively, at least a portion of the silicide layer SL may be in direct contact with the first etching stop layer 160. In an embodiment, the silicide layer SL may include, for example, a metal silicide material.

In an embodiment, the second etching stop layer 180 may be disposed on (e.g., disposed directly thereon) the top surfaces of the first interlayer insulating layer 170, the first etching stop layer 160, the first capping pattern 131, the second capping pattern 132, and the source/drain contact CA. FIGS. 2 and 4 illustrate that the second etching stop layer 180 is formed as a single film. However, embodiments of the present disclosure are not necessarily limited thereto. Alternatively, in some embodiments, the second etching stop layer 180 may be formed as a multifilm. In an embodiment, the second etching stop layer 180 may include at least one of, for example, aluminum oxide, aluminum nitride, hafnium oxide, zirconium oxide, silicon oxide, silicon nitride, silicon oxynitride, and a low-k material. The second interlayer insulating layer 190 may be disposed on (e.g., disposed directly thereon) the second etching stop layer 180. In an embodiment, the second interlayer insulating layer 190 may include at least one of, for example, silicon oxide, silicon nitride, silicon oxynitride, and a low-k material.

The via V may penetrate the second interlayer insulating layer 190 and the second etching stop layer 180 in the vertical direction DR3 and may thereby be connected to the source/drain contact CA. FIG. 2 illustrates that the via V is formed as a single film. However, embodiments of the present disclosure are not necessarily limited thereto. Alternatively, in some embodiments, the via V may be formed as a multifilm. The via V may include a conductive material.

In the embodiment of FIGS. 1 through 4, the sidewalls of the source/drain contact CA are not in direct contact with the source/drain region 140 and are spaced apart from the source/drain region (e.g., in the first direction DR1). Accordingly, it is possible to prevent the material of the source/drain contact CA from diffusing into the source/drain region 140 and eliminate the risk of a short circuit between the source/drain contact CA and the first and second gate electrodes G1 and G2.

A method of fabricating a semiconductor device according to some embodiments of the present disclosure will hereinafter be described with reference to FIGS. 2 through 19.

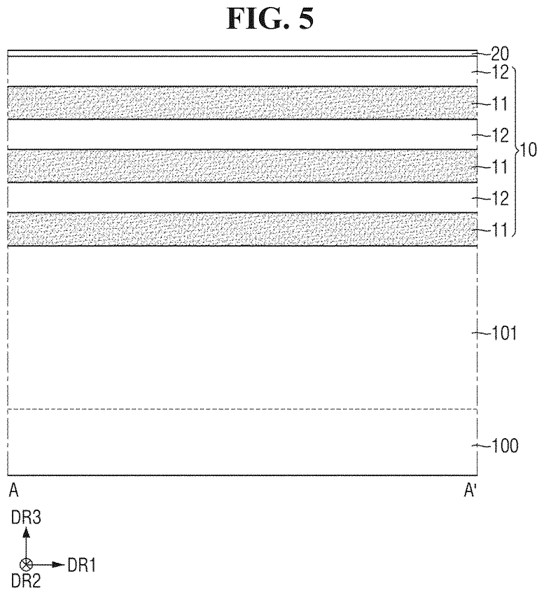

FIGS. 5 through 19 are cross-sectional views illustrating intermediate steps of a method of fabricating a semiconductor device according to some embodiments of the present disclosure.

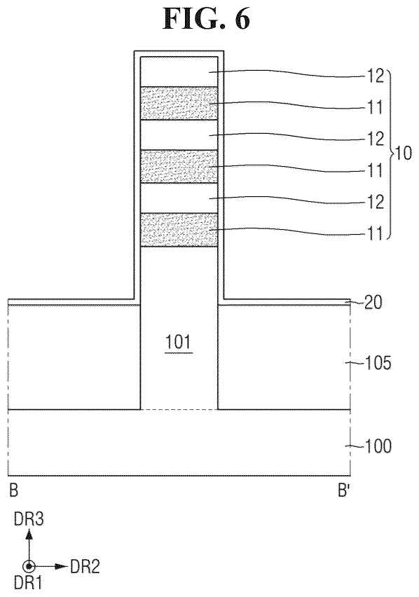

Referring to FIGS. 5 and 6, a stack structure 10 may include sacrificial layers 11 and semiconductor layers 12, which are alternately stacked on the substrate 100. For example, in an embodiment a sacrificial layer 11 may be formed as the lowermost layer of the stack structure 10, and a semiconductor layer 12 may be formed as the uppermost layer of the stack structure 10. However, embodiments of the present disclosure are not necessarily limited thereto. Alternatively, in some embodiments, a sacrificial layer 11 may also be formed as the uppermost layer of the stack structure 10. In an embodiment, the sacrificial layers 11 may include, for example, SiGe. The semiconductor layers 12 may include, for example, Si.

Thereafter, a portion of the stack structure 10 may be etched. When the stack structure 10 is being etched, a portion of the substrate 100 may also be etched. As a result, an active pattern 101 may be defined below the stack structure 10, on the top surface of the substrate 100. The active pattern 101 may extend in a first horizontal direction DR1. Thereafter, a field insulating layer 105 may be formed on (e.g. formed directly thereon) the top surface of the substrate 100. The field insulating layer 105 may surround the sidewalls of the active pattern 101. For example, the top surface of the active pattern 101 may be formed to be higher than the top surface of the field insulating layer 105.

Thereafter, a pad oxide layer 20 may be formed to cover the top surface of the field insulating layer 105, the exposed sidewalls of the active pattern 101, and the sidewalls and top surface of the stack structure 10. For example, the pad oxide layer 20 may be conformally formed. In an embodiment, the pad oxide layer 20 may include, for example, SiO2.

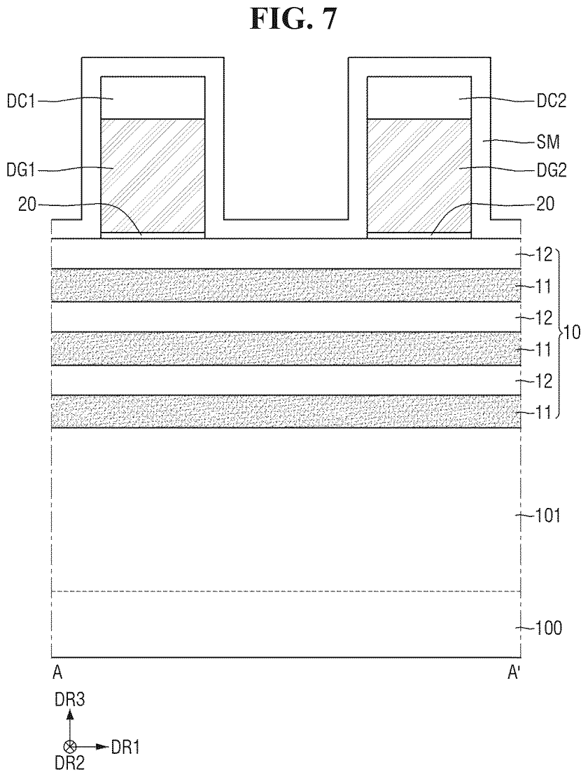

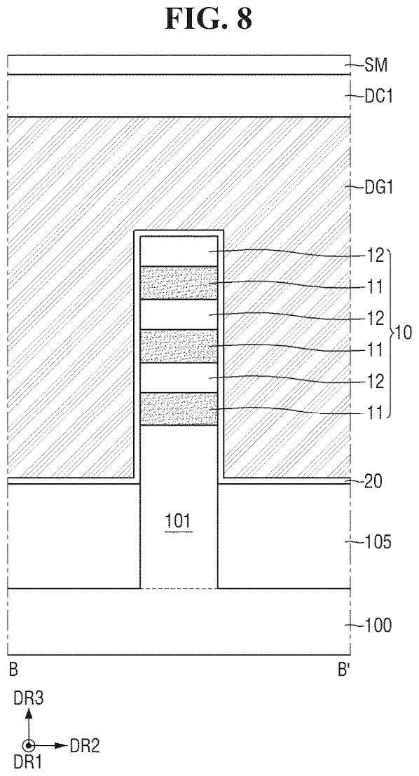

Referring to FIGS. 7 and 8, first and second dummy gates DG1 and DG2, which extend in a second horizontal direction DR2 on the pad oxide layer 20, and first and second dummy capping patterns DC1 and DC2 may be formed on the stack structure 10 and the field insulating layer 105. The first dummy capping pattern DC1 may be formed on (e.g., formed directly thereon) the first dummy gate DG1. The second dummy capping pattern DC2 may be formed on (e.g., formed directly thereon) the second dummy gate DG2. The second dummy gate DG2 and the second dummy capping pattern DC2 may be spaced apart in the first horizontal direction DR1 from the first dummy gate DG1 and the first dummy capping pattern DC1, respectively.

In an embodiment, during the formation of the first and second dummy gates DG1 and DG2 and the first and second dummy capping patterns DC1 and DC2, the entire pad oxide layer 20 except for portions that overlap with the first and second dummy gates DG1 and DG2 in a vertical direction DR3 on the substrate 100 may be removed.

Thereafter, a spacer material layer SM may be formed to cover the sidewalls of each of the first and second dummy gates DG1 and DG2, the sidewalls and top surface of each of the first and second dummy capping patterns DC1 and DC2, and the exposed sidewalls and the top surface of the stack structure 10, and the top surface of the field insulating layer 105. For example, the spacer material layer SM may be conformally formed. In an embodiment, the spacer material layer SM may include at least one of, for example, SiN, SiOCN, SiBCN, SiCN, SiON, and a combination thereof.

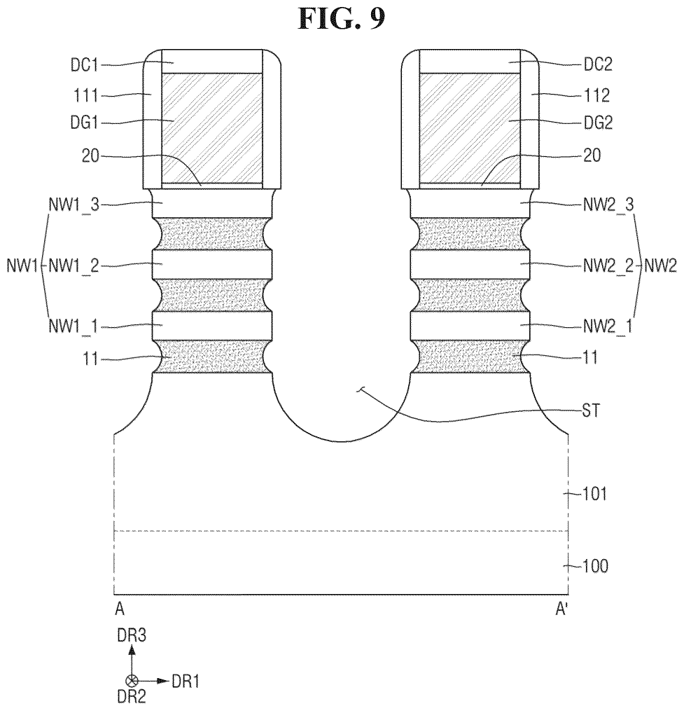

Referring to FIG. 9, a source/drain trench ST may be formed by etching the stack structure 10 using the first and second dummy capping patterns DC1 and DC2 and the first and second dummy gates DG1 and DG2 as a mask. For example, the source/drain trench ST may extend into the active pattern 101 (e.g., in the third direction DR3).

During the formation of the source/drain trench ST, portions of the first and second dummy capping patterns DC1 and DC2 and portions of the spacer material layer SM on the top surfaces of the first and second dummy capping patterns DC1 and DC2 may be removed. Portions of the spacer material layer SM that remain on the first dummy capping pattern DC1 and the sidewalls of the first dummy gate DG1 may be defined as first gate spacers 111. Also, portions of the spacer material layer SM that remain on the second dummy capping pattern DC2 and the sidewalls of the second dummy gate DG2 may be defined as second gate spacers 112.

After the formation of the source/drain trench ST, the semiconductor layers 12 that remain below the first dummy gate DG1 (e.g., in the third direction DR3) may be defined as a first plurality of nanosheets NW1, and the semiconductor layers 12 that remain below the second dummy gate DG2 (e.g., in the third direction DR3) may be defined as a second plurality of nanosheets NW2. For example, in an embodiment during the formation of the source/drain trench ST, the sacrificial layers 11 may be etched to a larger extent than the semiconductor layers 12. As a result, the sidewalls of each of the sacrificial layers 11 may become recessed into the sidewalls of each of the first nanosheets NW1 and the second nanosheets NW2.

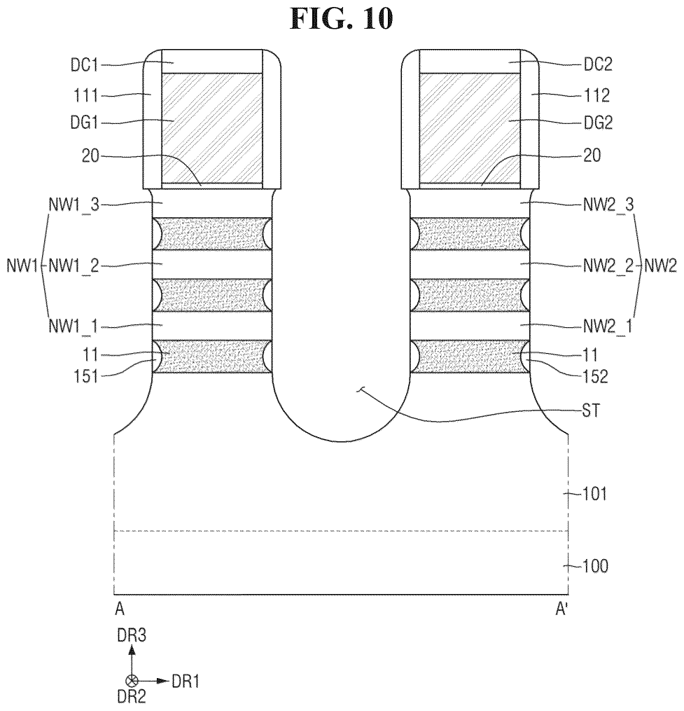

Referring to FIG. 10, first inner spacers 151 and second inner spacers 152 may be formed on the exposed recessed sidewalls of the sacrificial layers 11 in the first horizontal direction DR1, within the source/drain trench ST. For example, the first inner spacers 151 may be formed on both sidewalls (e.g., sidewalls that are spaced apart from each other in the first horizontal direction DR1) of the sacrificial layers 11 that are formed below the first dummy gate DG1, and the second inner spacers 152 may be formed on both sidewalls (e.g., sidewalls that are spaced apart from each other in the first horizontal direction DR1) of the sacrificial layers 11 that are formed below the second dummy gate DG2.

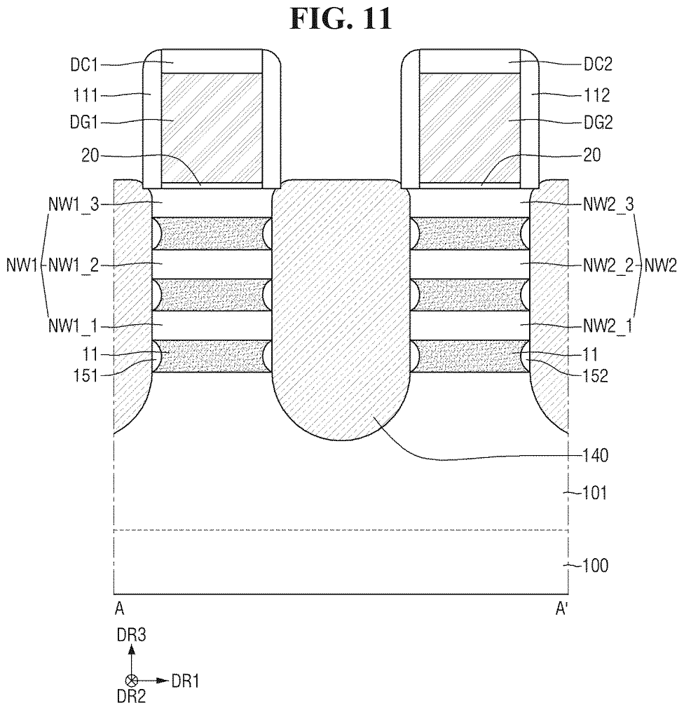

Referring to FIG. 11, a source/drain region 140 may be formed in the source/drain trench ST. For example, in an embodiment the top surface of the source/drain region 140 may be formed to be higher (e.g., in the third direction DR3) than the top surfaces of third and sixth nanosheets NW1_3 and NW2_3.

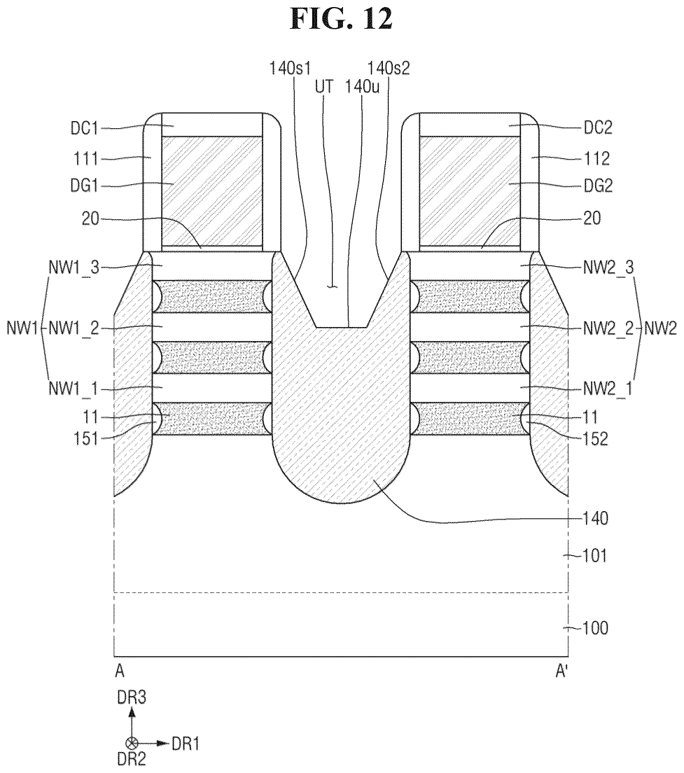

Referring to FIG. 12, an upper portion of the source/drain region 140 may be partially etched so that an upper trench UT may be formed. For example, the width in the first horizontal direction DR1 of the upper trench UT may gradually increase as the distance to the top surfaces of the third and sixth nanosheets NW1_3 and NW2_3 decreases. For example, both sidewalls, in the first horizontal direction DR1, of the source/drain region 140, exposed by the upper trench UT, may be defined as first and second inner sidewalls 140s1 and 140s2 of the source/drain region 140.

For example, the first inner sidewall 140s1 may have an inclined profile, extending from the bottom surface of the upper trench UT towards the sidewall of the third nanosheet NW1_3. For example, in a cross-sectional view taken along the first horizontal direction DR1, the first inner sidewall 140s1 of the source/drain region 140 may have a rectilinearly inclined profile. For example, the second inner sidewall 140s2 may have an inclined profile, extending from the bottom surface of the upper trench UT towards the sidewall of the sixth nanosheet NW2_3. For example, in the cross-sectional view taken along the first horizontal direction DR1, the second inner sidewall 140s2 of the source/drain region 140 may have a rectilinearly inclined profile. For example, a surface 140u of the source/drain region 140 that forms the bottom surface of the upper trench UT may be flat. For example, the surface 140u of the source/drain region 140 may be formed to be parallel to the top surface of the substrate 100.

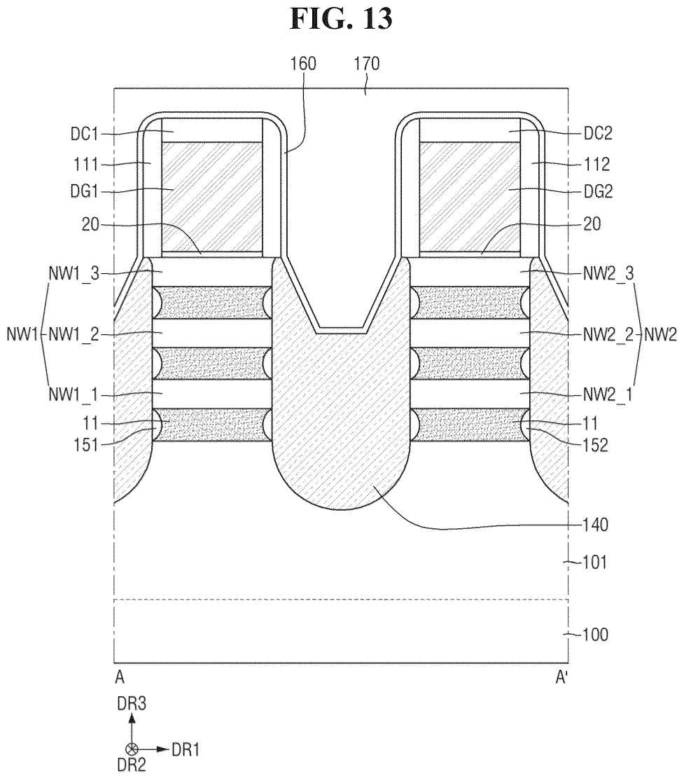

Referring to FIG. 13, a first etching stop layer 160 may be formed along (e.g., formed directly along) the surface of the exposed source/drain region 140. For example, the first etching stop layer 160 may be formed on (e.g., directly thereon) the first and second inner sidewalls 140s1 and 140s2 and the surface 140u of the source/drain region 140. The first etching stop layer 160 may also be formed on (e.g., directly thereon) the sidewalls of the first gate spacers 111, the sidewalls of the second gate spacers 112, the top surface of the first dummy capping pattern DC1, and the top surface of the first dummy capping pattern DC1. In an embodiment, the first etching stop layer 160 may also be formed on (e.g., directly thereon) the sidewalls, in the second horizontal direction DR2, of the source/drain region 140 and the top surface of the field insulating layer 105. For example, the first etching stop layer 160 may be conformally formed. Thereafter, a first interlayer insulating layer 170 may be formed on (e.g., directly thereon) the first etching stop layer 160.

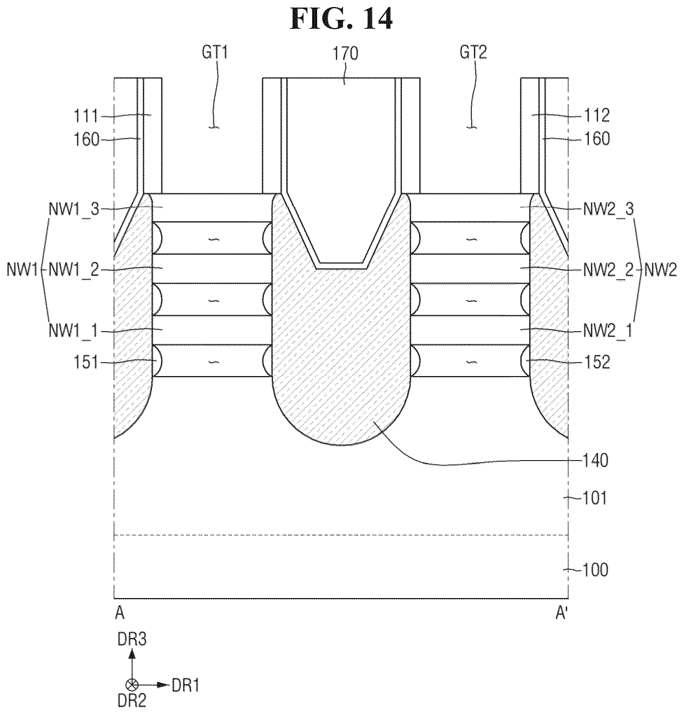

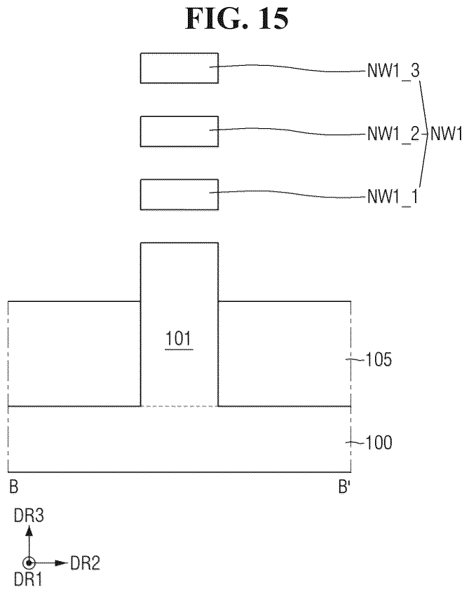

Referring to FIGS. 14 and 15, the top surfaces of the first and second dummy gates DG1 and DG2 may be exposed by a planarization process. Thereafter, the first and second dummy gates DG1 and DG2, the pad oxide layer 20, and the sacrificial layers 11 may be etched. The region where the first dummy gate DG1 has been etched away may be defined as a first gate trench GT1, and the region where the second dummy gate DG2 has been etched away may be defined as a second gate trench GT2.

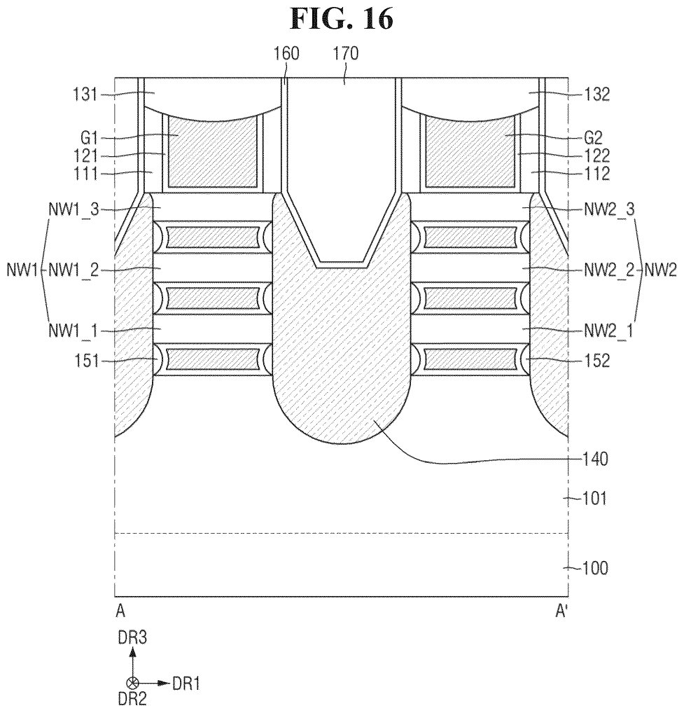

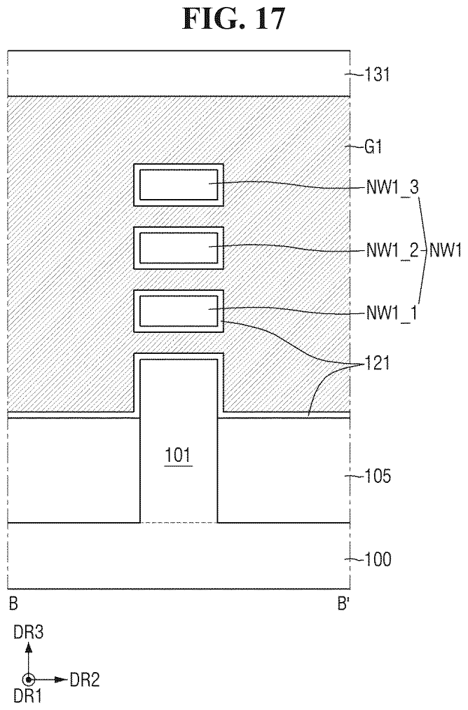

Referring to FIGS. 16 and 17, in an embodiment a first gate insulating layer 121, a first gate electrode G1, and a first capping pattern 131 may be sequentially formed in the regions where the first dummy gate DG1, the pad oxide layer 20, and the sacrificial layers 11 have been etched away. Also, a second gate insulating layer 122, a second gate electrode G2, and a second capping pattern 132 may be sequentially formed in the regions where the second gate insulating layer 122, the second dummy gate DG2, the pad oxide layer 20, and the sacrificial layers 11 have been etched away.

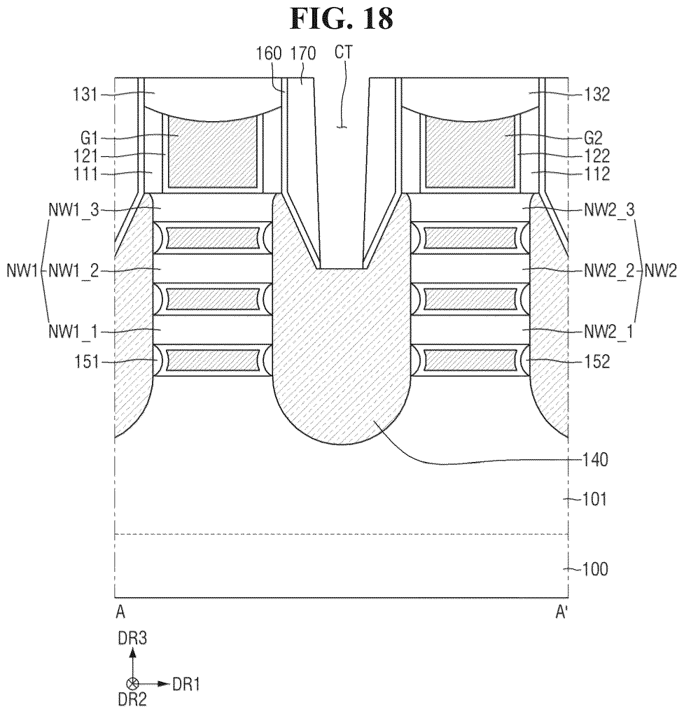

Referring to FIG. 18, in an embodiment a contact trench CT, which exposes the source/drain region 140 by penetrating the first interlayer insulating layer 170 and the first etching stop layer 160 in the vertical direction DR3, may be formed between the first gate spacers 111 and the second gate spacers 112 (e.g., in the first direction DR1). For example, both sidewalls that are spaced apart in the first horizontal direction DR1 of the contact trench CT may be spaced apart in the first horizontal direction DR1 from the first and second inner sidewalls 140s1 and 140s2 of the source/drain region 140 by the first interlayer insulating layer 170 and the first etching stop layer 160.

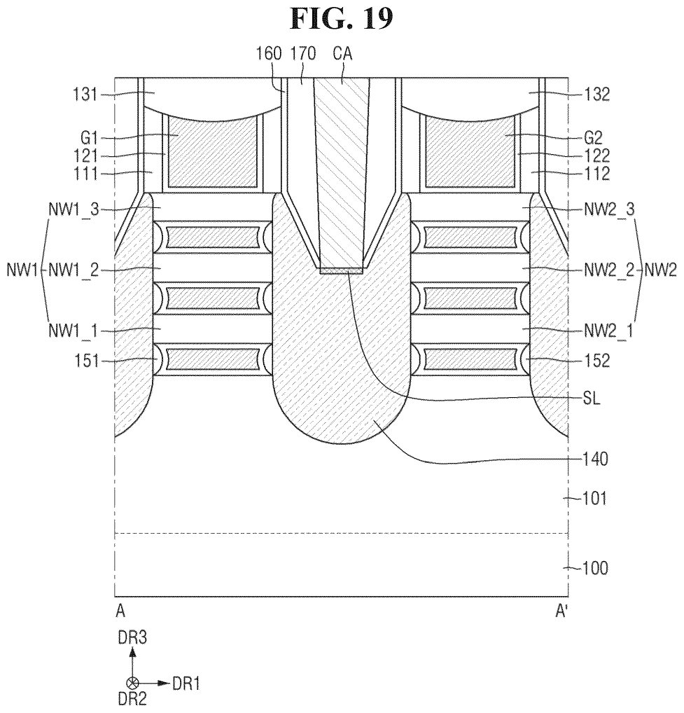

Referring to FIG. 19, a source/drain contact CA may be formed in the contact trench CT. For example, during the formation of the source/drain contact CA, a silicide layer SL may be formed between (e.g., directly between) the bottom surface of the source/drain contact CA and the source/drain region 140. For example, in an embodiment the silicide layer SL may not be formed on both sidewalls, in the first horizontal direction DR1, of the source/drain contact CA.

Thereafter, referring again to FIGS. 2 through 4, a second etching stop layer 180 and a second interlayer insulating layer 190 may be sequentially formed on the top surfaces of the first interlayer insulating layer 170, the first capping pattern 131, the second capping pattern 132, and the source/drain contact CA. Thereafter, a via V may be formed which is connected to the source/drain contact CA by penetrating the second interlayer insulating layer 190 and the second etching stop layer 180 in the vertical direction DR3. In this manner, the semiconductor device of FIGS. 2 and 4 can be obtained.

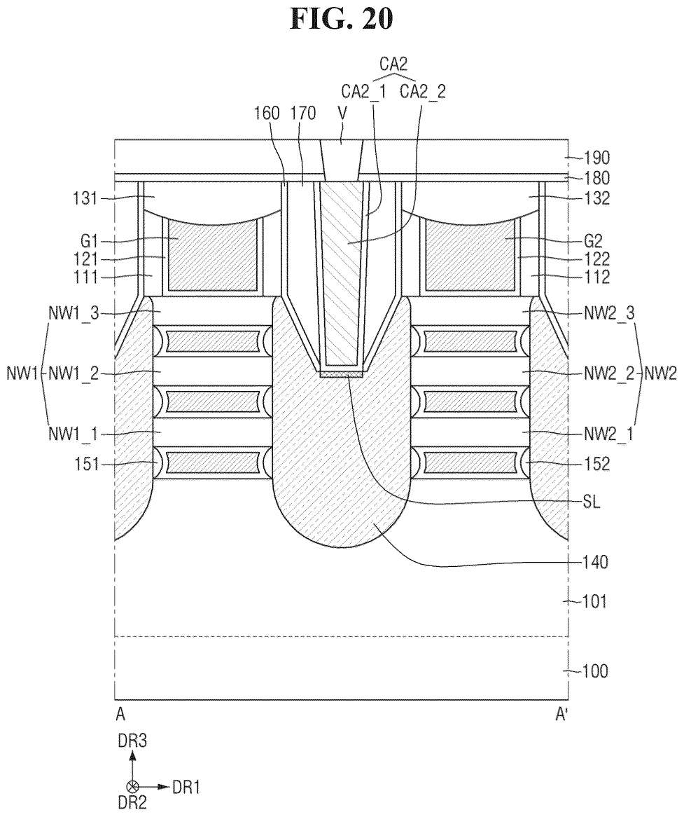

A semiconductor device according to some embodiments of the present disclosure will hereinafter be described with reference to FIG. 20, highlighting the differences with the semiconductor device of FIGS. 1 through 4 and a repeated description of similar or identical elements may be omitted for economy of description.

FIG. 20 is a cross-sectional view of a semiconductor device according to some embodiments of the present disclosure.

Referring to FIG. 20, a source/drain contact CA2 may be formed as a double film.

For example, in an embodiment the source/drain contact CA2 may include a barrier layer CA2_1 and a filling layer CA2_2. The barrier layer CA2_1 may form the sidewalls and bottom surface of the source/drain contact CA2. The filling layer CA2_2 may be disposed on (e.g., disposed directly thereon) the barrier layer CA2_1. For example, the filling layer CA2_2 may fill the gap between portions of the barrier layer CA2_1.

In an embodiment, the barrier layer CA2_1 may include at least one of, for example, Ta, TaN, Ti, TiN, Ru, Co, Ni, NiB, W, WN, Zr, ZrN, V, VN, Nb, NbN, Pt, Ir, and Rh. The filling layer CA2_2 may include at least one of, for example, Al, Cu, W, Co, Ru, and Mo.

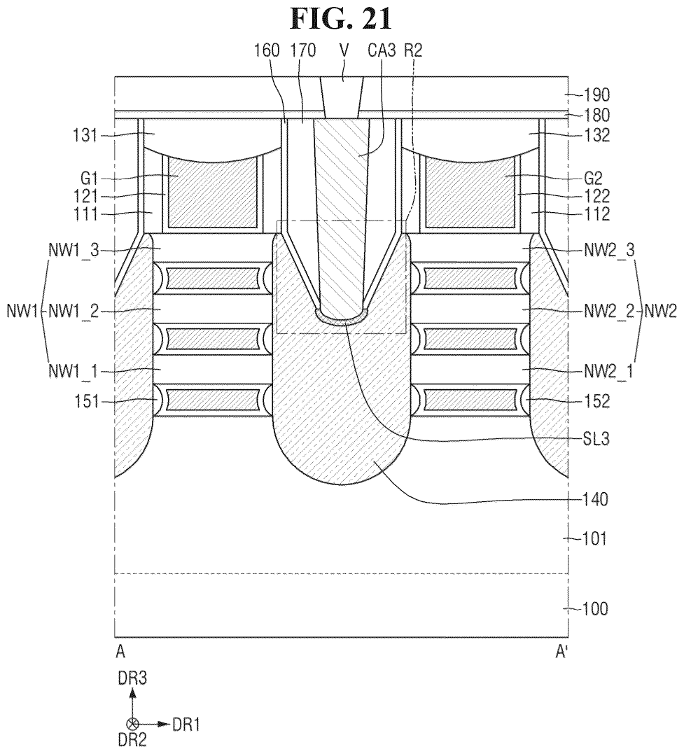

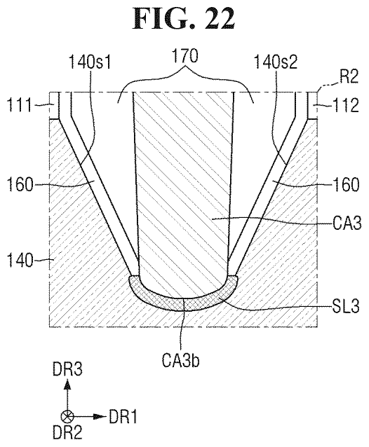

A semiconductor device according to some embodiments of the present disclosure will hereinafter be described with reference to FIGS. 21 and 22, highlighting the differences with the semiconductor device of FIGS. 1 through 4 and a repeated description of similar or identical elements may be omitted for economy of description.

FIG. 21 is a cross-sectional view of a semiconductor device according to some embodiments of the present disclosure. FIG. 22 is an enlarged cross-sectional view of a region R2 of FIG. 21.

Referring to FIGS. 21 and 22, a bottom surface CA3b of a source/drain contact CA3 may have a convex curved shape towards the top surface of a substrate 100 and may not be flat. For example, a silicide layer SL may be disposed between (e.g., disposed directly therebetween) the bottom surface CA3b of the source/drain contact CA3 and a source/drain region 140. For example, at least a portion of the silicide layer SL3 may be in direct contact with a first etching stop layer 160, such as a bottom surface of the first etching stop layer 160.

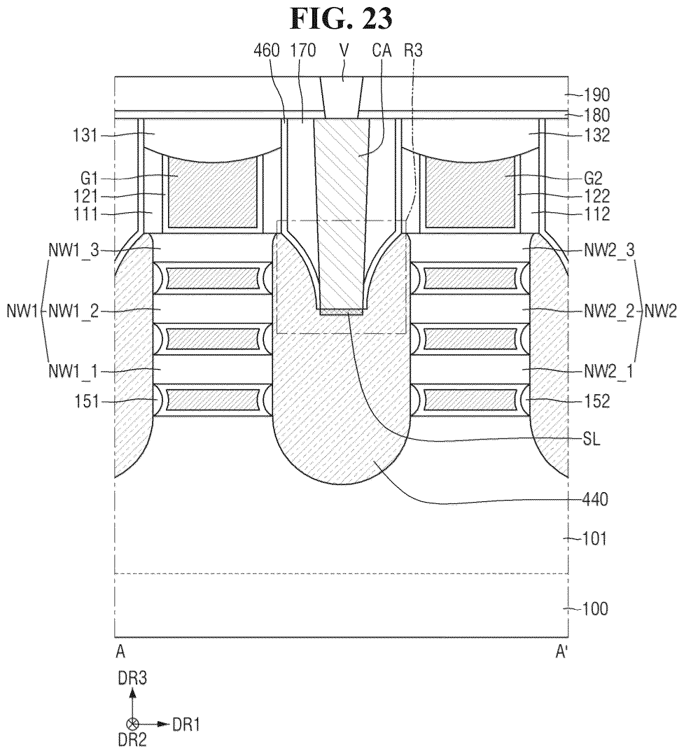

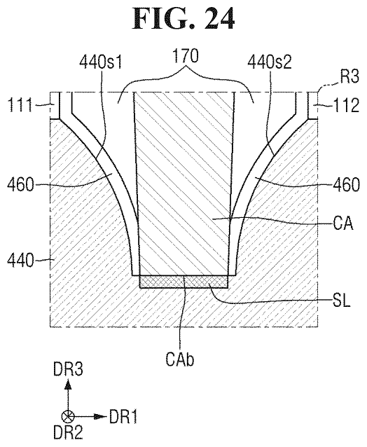

A semiconductor device according to some embodiments of the present disclosure will hereinafter be described with reference to FIGS. 23 and 24, highlighting the differences with the semiconductor device of FIGS. 1 through 4 and a repeated description of similar or identical elements may be omitted for economy of description.

FIG. 23 is a cross-sectional view of a semiconductor device according to some embodiments of the present disclosure. FIG. 24 is an enlarged cross-sectional view of a region R3 of FIG. 23.

Referring to FIGS. 23 and 24, first and second inner sidewalls 440s1 and 440s2 of a source/drain region 440 may have a convex shape towards their respective sidewalls, in a first horizontal direction DR1, of a source/drain contact CA.

For example, the first inner sidewall 440s1 of the source/drain region 440 that faces a first sidewall, in the first horizontal direction DR1, of the source/drain contact CA may have a convex inclined profile extending towards the first sidewall, in the first horizontal direction DR1, of the source/drain contact CA, and the second inner sidewall 440s2 of the source/drain region 440 that faces a second sidewall, in the first horizontal direction DR1, of the source/drain contact CA may have a convex inclined profile towards the second sidewall, in the first horizontal direction DR1, of the source/drain contact CA. A first etching stop layer 460 may be disposed along the first and second sidewalls 440s1 and 440s2 of the source/drain region 440.

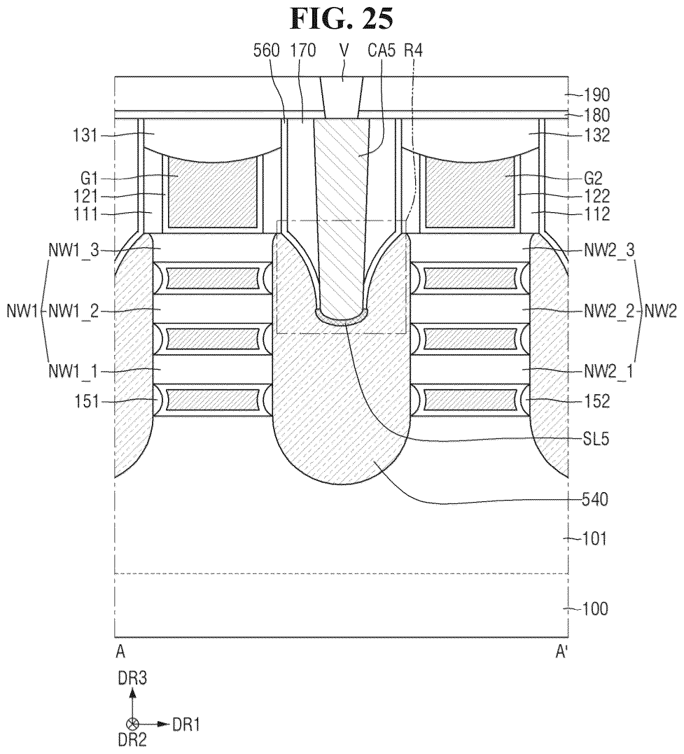

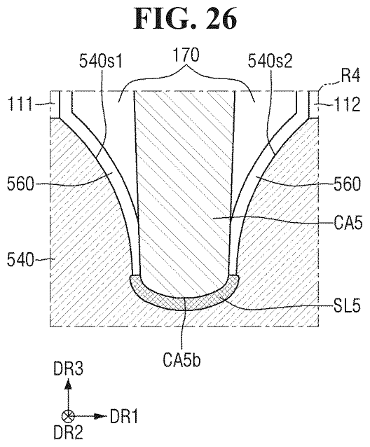

A semiconductor device according to some embodiments of the present disclosure will hereinafter be described with reference to FIGS. 25 and 26, highlighting the differences with the semiconductor device of FIGS. 1 through 4 and a repeated description of similar or identical elements may be omitted for economy of description.

FIG. 25 is a cross-sectional view of a semiconductor device according to some embodiments of the present disclosure. FIG. 26 is an enlarged cross-sectional view of a region R4 of FIG. 25.

Referring to FIGS. 25 and 26, a bottom surface CA5b of a source/drain contact CA5 may have a convex curved shape towards the top surface of a substrate 100. For example, a silicide layer SLS may be disposed between (e.g., disposed directly therebetween) the bottom surface CA5b of the source/drain contact CA5 and a source/drain region 540. For example, at least a portion of the silicide layer SLS may be in direct contact with a first etching stop layer 560.

First and second inner sidewalls 540s1 and 540s2 of a source/drain region 540 may have a convex shape extending towards their respective sidewalls, in a first horizontal direction DR1, of a source/drain contact CA5.

For example, the first inner sidewall 540s1 of the source/drain region 540 that faces a first sidewall, in the first horizontal direction DR1, of the source/drain contact CA5 may have a convex inclined profile extending towards the first sidewall, in the first horizontal direction DR1, of the source/drain contact CA5, and the second inner sidewall 540s2 of the source/drain region 540 that faces a second sidewall, in the first horizontal direction DR1, of the source/drain contact CA5 may have a convex inclined profile extending towards the second sidewall, in the first horizontal direction DR1, of the source/drain contact CA5. The first etching stop layer 560 may be disposed along the first and second sidewalls 540s1 and 540s2 of the source/drain region 540.

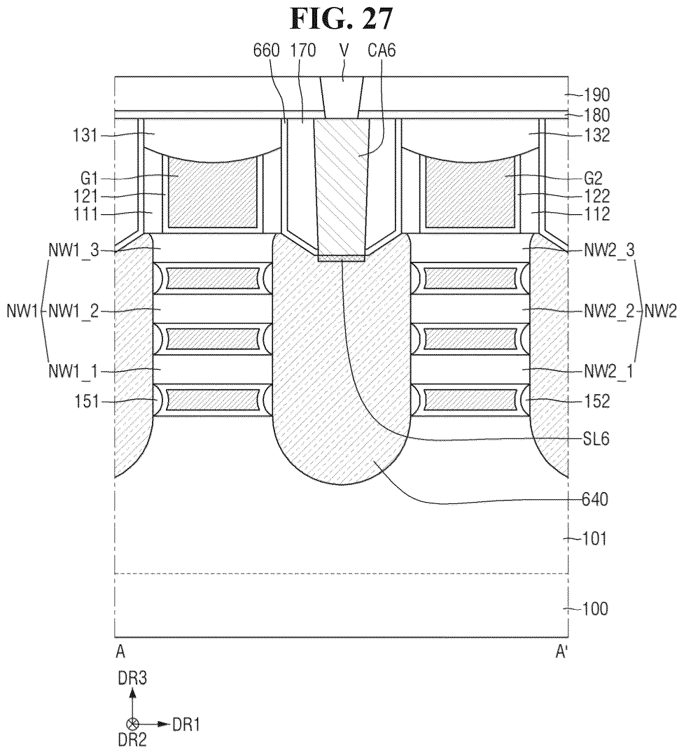

A semiconductor device according to some embodiments of the present disclosure will hereinafter be described with reference to FIG. 27, highlighting the differences with the semiconductor device of FIGS. 1 through 4 and a repeated description of similar or identical elements may be omitted for economy of description.

FIG. 27 is a cross-sectional view of a semiconductor device according to some embodiments of the present disclosure.

Referring to FIG. 27, the bottom surface of a source/drain contact CA6 may be formed to overlap the third and sixth nanosheets NW1_3 and NW2_3 (e.g., in the first direction DR1).

For example, the bottom surface of the source/drain contact CA6 may be formed to overlap the sidewalls of the third nanosheet NW1_3 and the sidewalls of the sixth nanosheet NW2_3 along the first direction DR1. A silicide layer SL6 may be disposed between (e.g., disposed directly therebetween) the bottom surface of the source/drain contact CA6 and a source/drain region 640. A first etching stop layer 660 may be disposed between (e.g. disposed directly therebetween) the source/drain region 640 and a first interlayer insulating layer 170.

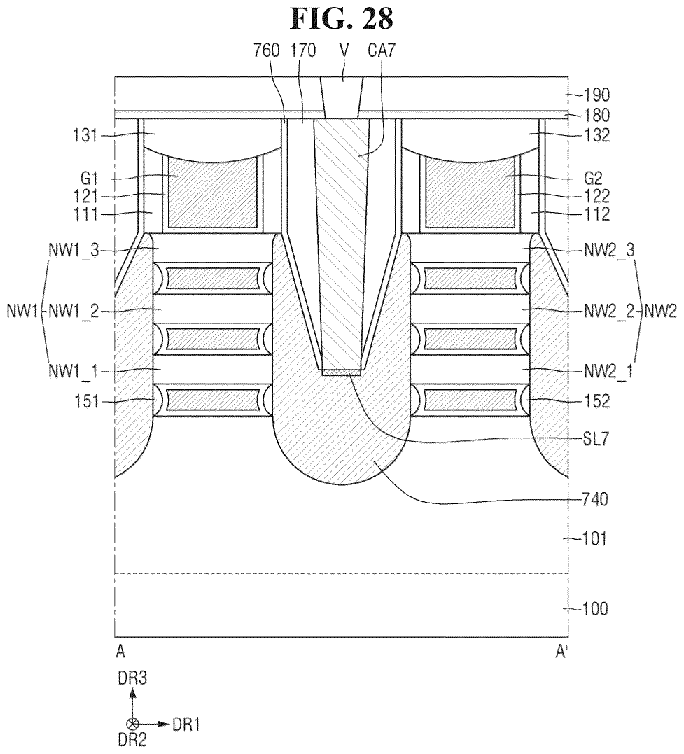

A semiconductor device according to some embodiments of the present disclosure will hereinafter be described with reference to FIG. 28, highlighting the differences with the semiconductor device of FIGS. 1 through 4 and a repeated description of similar or identical elements may be omitted for economy of description.

FIG. 28 is a cross-sectional view of a semiconductor device according to some embodiments of the present disclosure.

Referring to FIG. 28, the bottom surface of a source/drain contact CA7 may be formed to overlap the first and fourth nanosheets NW1_1 and NW2_1 along the first direction DR1.

For example, the bottom surface of the source/drain contact CA7 may be formed to overlap the sidewalls of the first nanosheet NW1_1 and the sidewalls of the fourth nanosheet NW2_1 along the first direction DR1. A silicide layer SL7 may be disposed between (e.g., disposed directly therebetween) the bottom surface of the source/drain contact CA7 and a source/drain region 740. A first etching stop layer 760 may be disposed between (e.g., disposed directly therebetween) the source/drain region 740 and a first interlayer insulating layer 170.

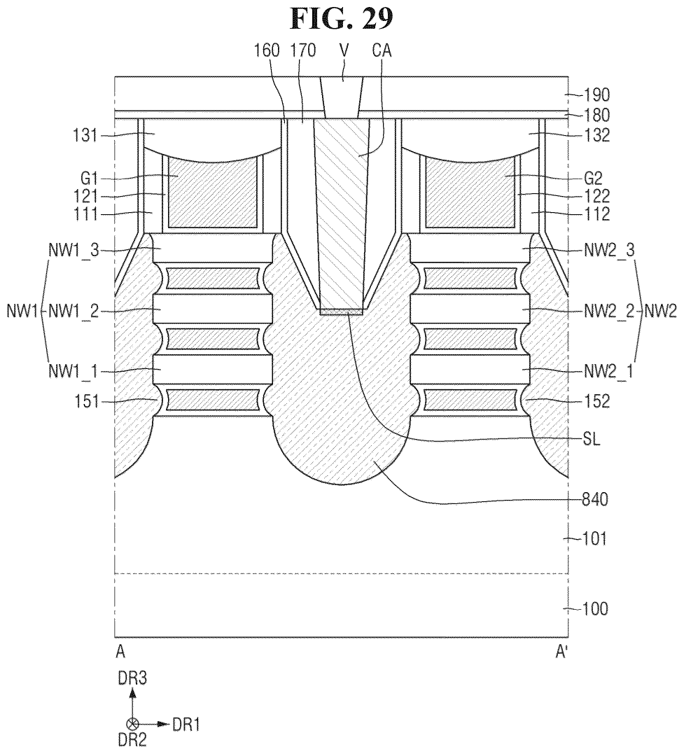

A semiconductor device according to some embodiments of the present disclosure will hereinafter be described with reference to FIG. 29, highlighting the differences with the semiconductor device of FIGS. 1 through 4 and a repeated description of similar or identical elements may be omitted for economy of description.

FIG. 29 is a cross-sectional view of a semiconductor device according to some embodiments of the present disclosure.

Referring to FIG. 29, the semiconductor device may not include first inner spacers (151; FIG. 2) and second inner spacers (152; FIG. 2).

For example, a source/drain region 840 may be in direct contact with a first gate insulating layer 121, between first, second, and third nanosheets NW1_1, NW1_2, and NW1_3. The source/drain region 840 may also be in contact with the first gate insulating layer 121, between an active pattern 101 and the first nanosheet NW1_1. For example, the source/drain region 840 may be in direct contact with a second gate insulating layer 122, between fourth, fifth, and sixth nanosheets NW2_1, NW2_2, and NW2_3. The source/drain region 840 may also be in direct contact with the second gate insulating layer 122, between the active pattern 101 and the fourth nanosheet NW2_1.

Non-limiting embodiments of the present disclosure have been described above with reference to the accompanying drawings. However, embodiments of the present disclosure are not necessarily limited thereto and embodiments of the present disclosure may be implemented in various different forms. It will be understood that the present disclosure can be implemented in other specific forms without changing the technical spirit or gist of the present disclosure. Therefore, it should be understood that the described embodiments set forth herein are illustrative in all respects and not limiting.

What is claimed is:

1. A semiconductor device comprising:
a substrate;
an active pattern on the substrate, the active pattern extending in a first horizontal direction;
first, second, and third nanosheets sequentially stacked on the active pattern, the first to third nanosheets are spaced apart from each other in a vertical direction, wherein the third nanosheet is an uppermost nanosheet of the first to third nanosheets;
a gate electrode on the active pattern and extending in a second horizontal direction crossing the first horizontal direction, the gate electrode surrounding each of the first, second, and third nanosheets;
a source/drain region on the active pattern and disposed on at least one side of the gate electrode;
an interlayer insulating layer covering the source/drain region; and
a source/drain contact penetrating the interlayer insulating layer in the vertical direction, the source/drain contact is connected to the source/drain region,
wherein at least a portion of the interlayer insulating layer is disposed between sidewalls of the source/drain contact and the source/drain region in the first horizontal direction, the at least portion of the interlayer insulating layer overlapping sidewalls of the third nanosheet along the first horizontal direction.

2. The semiconductor device of claim 1, further comprising:
an etching stop layer disposed between the source/drain region and the interlayer insulating layer,
wherein at least a portion of the etching stop layer is disposed between the sidewalls of the source/drain contact and the sidewalls of the source/drain region in the first horizontal direction, the at least portion of the etching stop layer overlapping the third nanosheet along the first horizontal direction.

3. The semiconductor device of claim 1, wherein the sidewalls of the source/drain contact do not directly contact the source/drain region.

4. The semiconductor device of claim 1, further comprising:
a silicide layer disposed between a bottom surface of the source/drain contact and the source/drain region,
wherein the silicide layer is not disposed on the sidewalls of the source/drain contact.

5. The semiconductor device of claim 1, wherein inner sidewalls of the source/drain region that face the sidewalls of the source/drain contact have a rectilinearly inclined profile extending from a bottom surface of the source/drain contact towards the sidewalls of the third nanosheet.

6. The semiconductor device of claim 1, wherein inner sidewalls of the source/drain region that face the sidewalls of the source/drain contact have a convex inclined profile extending towards the sidewalls of the source/drain contact.

7. The semiconductor device of claim 1, wherein a bottom surface of the source/drain contact is flat.

8. The semiconductor device of claim 1, wherein a bottom surface of the source/drain contact has a convex curved shape extending towards the substrate.

9. The semiconductor device of claim 1, further comprising:
an inner spacer disposed between the source/drain region and a portion of the gate electrode positioned between each of the first, second, and third nanosheets and between the source/drain region and a portion of the gate electrode positioned between the first nanosheet and the active pattern.

10. The semiconductor device of claim 1, wherein the source/drain contact is composed of a single film.

11. The semiconductor device of claim 1, wherein the source/drain contact includes a barrier layer defining the sidewalls and a bottom surface of the source/drain contact, and a filling layer disposed on the barrier layer.

12. The semiconductor device of claim 1, wherein a bottom surface of the source/drain contact overlaps sidewalls of the second nanosheet along the first horizontal direction.

13. A semiconductor device comprising:
a substrate;
an active pattern on the substrate, the active pattern extending in a first horizontal direction;
first, second, and third nanosheets sequentially stacked on the active pattern, the first to third nanosheets are spaced apart from each other in a vertical direction, wherein the third nanosheet is an uppermost nanosheet of the first to third nanosheets;
a gate electrode on the active pattern, the gate electrode extending in a second horizontal direction crossing the first horizontal direction, the gate electrode surrounding each of the first, second, and third nanosheets;
a source/drain region on the active pattern and disposed on at least one side of the gate electrode;
an etching stop layer disposed along a top surface of the source/drain region;
a source/drain contact penetrating the etching stop layer in the vertical direction, the source/drain contact is connected to the source/drain region; and
a silicide layer disposed between a bottom surface of the source/drain contact and the source/drain region, wherein the silicide layer is not disposed on sidewalls of the source/drain contact,
wherein at least a portion of the etching stop layer is disposed between sidewalls of the source/drain contact and the source/drain region, the at least portion of the etching stop layer overlapping sidewalls of the third nanosheet along the first horizontal direction.

14. The semiconductor device of claim 13, further comprising:
an interlayer insulating layer disposed on the etching stop layer, the interlayer insulating layer surrounding the sidewalls of the source/drain contact,
wherein at least a portion of the interlayer insulating layer is disposed between the sidewalls of the source/drain contact and the source/drain region, the at least portion of the interlayer insulating layer overlapping the third nanosheet along the first horizontal direction.

15. The semiconductor device of claim 13, wherein inner sidewalls of the source/drain region that face the sidewalls of the source/drain contact have a rectilinearly inclined profile extending from the bottom surface of the source/drain contact towards the sidewalls of the third nanosheet.

16. The semiconductor device of claim 13, wherein the source/drain contact is composed of a single film.

17. The semiconductor device of claim 13, further comprising:
a gate insulating layer disposed between the gate electrode and the first, second, and third nanosheets and between the gate electrode and the source/drain region, the gate insulating layer is in direct contact with the source/drain region.

18. The semiconductor device of claim 13, wherein the bottom surface of the source/drain contact overlaps the sidewalls of the third nanosheet along the first horizontal direction.

19. The semiconductor device of claim 13, wherein the bottom surface of the source/drain contact overlaps sidewalls of the first nanosheet along the first horizontal direction.

20. A semiconductor device comprising:
a substrate;
an active pattern on the substrate, the active pattern extending in a first horizontal direction on the substrate;
first, second, and third nanosheets sequentially stacked on the active pattern, the first to third nanosheets are spaced apart from each other in a vertical direction, wherein the third nanosheet is an uppermost nanosheet of the first to third nanosheets;
a gate electrode on the active pattern and extending in a second horizontal direction crossing the first horizontal direction, the gate electrode surrounding each of the first, second, and third nanosheets;
a source/drain region on the active pattern and disposed on at least one side of the gate electrode;
an etching stop layer disposed along a top surface of the source/drain region;
an interlayer insulating layer disposed on the etching stop layer;
a source/drain contact penetrating the etching stop layer and the interlayer insulating layer in the vertical direction, the source/drain contact is connected to the source/drain region; and
a silicide layer disposed between a bottom surface of the source/drain contact and the source/drain region, the silicide layer is not disposed on sidewalls of the source/drain contact,
wherein at least a portion of the etching stop layer and at least a portion of the interlayer insulating layer is disposed between the sidewalls of the source/drain contact and the source/drain region, the at least portion of the etching stop layer and the at least portion of the interlayer insulating layer overlapping the third nanosheet along the first horizontal direction; and
wherein inner sidewalls of the source/drain region that face the sidewalls of the source/drain contact have a rectilinearly inclined profile extending from the bottom surface of the source/drain contact towards the sidewalls of the third nanosheet.
